(19) United States
(12) Patent Application Publication
(10) Pub. No.: US 2025/0275207 A1
(43) Pub. Date: Aug. 28, 2025

(54) HYBRID GaN AND BCD DEVICES USING HETEROEPITAXY ON SILICON

(71) Applicant: Allegro MicroSystems, LLC, Manchester, NH (US)

(72) Inventors: Thomas S. Chung, Merrimack, NH (US); Maxim Klebanov, Palm Coast, FL (US); Kevin Kim, Chandler, AZ (US); Chung C. Kuo, Manchester, NH (US); Felix Palumbo, Buenos Aires (AR)

(73) Assignee: Allegro MicroSystems, LLC, Manchester, NH (US)

(21) Appl. No.: 18/589,545

(22) Filed: Feb. 28, 2024

(51) Int. Cl. H01L 29/20; H01L 21/02; H01L 23/31; H01L 27/092; H01L 29/04; H01L 29/66; H01L 29/735

(52) U.S. Cl. CPC H10D 62/8503; H01L 21/02422; H01L 21/02433; H01L 21/0254; H01L 23/3171; H10D 10/061; H10D 10/60; H10D 62/405; H10D 84/85

(57) ABSTRACT

According to one aspect of the present disclosure, a semiconductor device includes a first substrate having a lattice structure, wherein the first substrate includes a gallium nitride (GaN) area adjacent to a bipolar junction transistor (BJT) complementary metal oxide semiconductor (CMOS) double diffused metal oxide semiconductor (DMOS) (BCD) area. In some embodiments, the GaN area comprises one or more GaN device layers disposed on the first substrate. In some embodiments, the BCD area comprises one or more BCD device layers. In some embodiments, the first substrate comprises a silicon (100) lattice structure configuration. In some embodiments, the GaN devices layers comprise one or more GaN device layers having a cubic structure and one or more GaN device layers having a wurtzite structure.

### BACKGROUND

A bipolar junction transistor (which may herein be referred to as a BJT or bipolar) complementary metal oxide semiconductor (CMOS) double diffused metal oxide semiconductor (DMOS) (BCD) device combines the strengths of three technologies onto a single integrated circuit (IC). A BJT enables high precision analog signal control. A low voltage CMOS transistor is commonly used in applications for high density digital circuits. A DMOS transistor is a type of power transistor commonly used in high voltage applications. The BCD device maybe disposed on a silicon wafer.

Some semiconductor devices utilize non-homogeneous semiconductor layers. Device layers may include one or more elements, such as gallium nitride (GaN) layers, aluminum nitride (AlN) layers, and aluminum gallium nitride (AlGaN) layers. The non-homogeneous semiconductor layers maybe disposed on a silicon wafer.

### SUMMARY

According to one aspect of the present disclosure, a semiconductor device includes a first substrate having a lattice structure, wherein the first substrate includes a gallium nitride (GaN) area adjacent to a bipolar junction transistor (BJT) complementary metal oxide semiconductor (CMOS) double diffused metal oxide semiconductor (DMOS) (BCD) area. In some embodiments, the GaN area comprises one or more GaN device layers disposed on the first substrate. In some embodiments, the BCD area comprises one or more BCD device layers. In some embodiments, the first substrate comprises a silicon (100) lattice structure configuration.

According to one aspect of the present disclosure, a method for forming a semiconductor device includes forming a first substrate having a lattice structure. In some embodiments, the method includes forming a gallium nitride (GaN) area on the first substrate. In some embodiments, the method includes forming a bipolar junction transistor (BJT) complementary metal oxide semiconductor (CMOS) double diffused metal oxide semiconductor (DMOS) (BCD) area adjacent to the GaN area on the first substrate. In some embodiments, forming the GaN area comprises depositing one or more GaN device layers on the first substrate. In some embodiments, forming the BCD area comprises depositing one or more BCD device layers. In some embodiments, the first substrate comprises a silicon (100) lattice structure configuration.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1 is a side view of a cross section of a semiconductor device having a gallium nitride (GaN) area adjacent to a bipolar junction transistor (BJT) complementary metal oxide semiconductor (CMOS) double diffused metal oxide semiconductor (DMOS) (BCD) area;

FIG. 2 is a flowchart of an example of a process to fabricate the semiconductor device of FIG. 1;

FIG. 3A is a side view of a cross section of a semiconductor device having a substrate;

FIG. 3B is a side view of a cross section of a semiconductor device having a substrate with the GaN area formed on the substrate;

FIG. 3C is a side view of a cross section of a semiconductor device having the BCD area formed adjacent to the GaN area on the substrate;

FIG. 3D is a side view of a cross section of a semiconductor device having a borophosphosilicate glass (BPSG) layer deposited, and one or more gate contacts, source contacts, and drain contacts formed;

FIG. 3E is a side view of a cross section of a semiconductor device having metallization layer deposited on the BPSG layer, gate contacts, source contacts, and drain contacts;

FIG. 4 is a flowchart of an example of a process to fabricate the GaN area for the semiconductor device of FIG. 1; and

FIG. 5 is a flowchart of an example of a process to fabricate the BCD area for the semiconductor device of FIG. 1.

### DETAILED DESCRIPTION

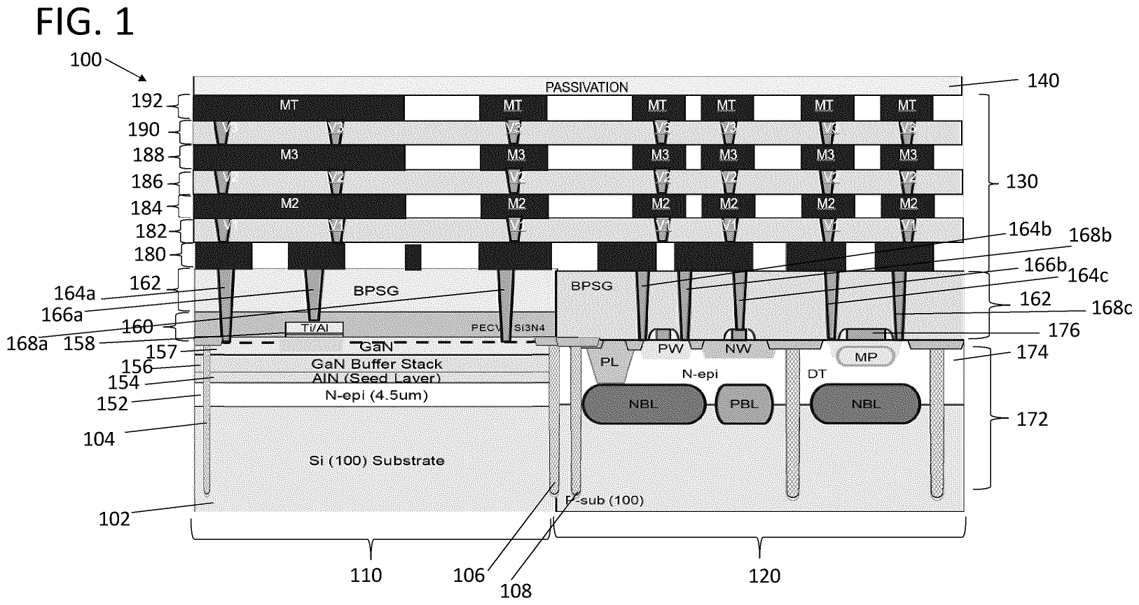

FIG. 1 shows a semiconductor device 100 comprising a substrate 102 having a gallium nitride (GaN) area 110 adjacent to a bipolar junction transistor (BJT) complementary metal oxide semiconductor (CMOS) double diffused metal oxide semiconductor (DMOS) (BCD) area 120. One or more metallization layers 130 are disposed on the GaN area 110 and the BCD area 120. Disposed on the metallization layers 130 is a passivation layer 140.

In example embodiments, the substrate 102 is formed from a silicon (100) wafer formed from a single crystal with a lattice structure that is defined by the orientation. Orientation refers to the growth plane of the crystalline silicon. Different crystallographic planes and directions have different arrangements of atoms or lattices when viewed by a particular angle. The different views of the crystallographic orientation of the surface of the wafer may be referred to as silicon (100), silicon (110), and silicon (111). The orientation of these planes and directions can affect the properties of the wafer and resulting device fabricated atop it.

Silicon (100) refers to the crystallographic plane and direction of the crystal lattice of the silicon wafer. The (100) direction is formed along a line parallel to the y-axis of the crystal lattice. The crystal plane of the silicon (100) is perpendicular to the y- axis of the crystal lattice. Silicon (100) may be referred to herein as a cubic or diamond cubic lattice structure. It is understood that the substrate 102 is one substrate with one lattice structure, but may be referred to herein as a GaN area substrate and a BCD area substrate to facilitate an understanding of the disclosure. The substrate 102 may be doped with a p-type dopant with a resistivity of 5 ohm-cm.

In the illustrated embodiment, one or more deep trench structures 104, 106, 108 isolate the GaN area 110 and the BCD area 120. A first deep trench structure 104 and a second deep trench structure 106 are positioned on opposing sides of the GaN area 110. A third deep trench structure 108 is positioned adjacent to the second deep trench structure 106, in the BCD area 120. The deep trench structures isolate the voltages and temperatures of the respective GaN area 110 and the BCD area 120. Multiple deep trench structures may be used to further isolate the two areas. It will be appreciated by those of ordinary skill in the art, that although three deep trenches 104, 106, 108 are shown other numbers of deep trenches are possible including more or fewer deep trenches.

The GaN area 110 comprises an epitaxial layer 152 disposed on the substrate 102. The epitaxial layer 152 may be doped with an n-type dopant to form an n-type epitaxial layer. One or more GaN device layers 154, 156, 157 are disposed on the epitaxial layer 152. The GaN device layers 154, 156, 157 comprise one or more layers having a cubic structure and one or more layers having a wurtzite structure. In embodiments, GaN device layer 154 comprises an aluminum nitride (AlN) layer disposed on the epitaxial layer 152. GaN device layer 156 is disposed on the GaN device layer 154. GaN device layer 157 is disposed on the GaN device layer 156.

Disposed on the GaN device layers 154, 156, 157 is a structure 158 formed out of an aluminum gallium nitride (AlGaN) layer, a GaN layer, and a gate metal layer. Disposed on GaN device layer 157 and the structure 158 is a passivation layer 160. The structure 158 is a p-GaN that is heavily doped by Magnesium (Mg) to form p-type area. This p-GaN depletes 2-Dimensional Electron Gas (2DEG) under the gate so that enables Enhanced Mode of GaN device. Disposed on the passivation layer 160 is a borophosphosilicate glass (BPSG) layer 162.

In embodiments, the BCD area 120 of the substrate 102 may be doped with a p-type dopant in order to form a p-type layers like p-type well (PW), medium deep implanted p-type well (MP), or p+buried layer (PBL). The BCD area 120 comprises an epitaxial layer 174 disposed on the substrate 102. The epitaxial layer 174 may be doped with an n-type dopant in order to form an n-type layers like n-type well (NW), plug layer implant (PL), or n+buried layer (NBL). One or more bipolar junction transistor (BJT), complementary metal oxide semiconductor (CMOS), and double diffused metal oxide semiconductor (DMOS) (BCD) elements 172 are disposed within the BCD area 120 of the substrate 102 and the epitaxial layer 174. A gate polysilicon layer 176 is disposed on the BCD elements 172. The BPSG layer 162 is disposed on the passivation layer 160 and the BCD elements 172.

One or more contacts 164a, 164b, 164c, 166a, 166b, 168a, 168b, 168c are formed within the BPSG layer 162. The contacts (which may be referred to herein as “vias”) extend from the metallization layers 130 to provide conductive paths from the source, gate, and drain, for example. A first source contact 164a, a first gate contact 166a, and a first drain contact 168a are formed in the BPSG layer 162 and the passivation layer 160 in the GaN area 110. A second source contact 164b, a third source contact 164c, a second gate contact 166b, a second drain contact 168b, and a third drain contact 168c are formed in the BPSG layer 162 in the BCD area 120. The contacts 164a, 164b, 164c, 166a, 166b, 168a, 168b, 168c provide conductive paths from the metallization layers 130 to the device layer elements (such as the GaN device layers 154, 156, 157, and BCD elements 172).

In embodiments, the metallization layers 130 are formed above the GaN area 110 and the BCD area 120 of the substrate 102. In the illustrated embodiment, the metallization layers 130 comprise a first metal layer 180 over the BPSG layer 162. A first metallization layer 182 is disposed on the first metal layer 180. A second metal layer 184 is disposed on the first metallization layer 182. A second metallization layer 186 is disposed on the second metal layer 184. A third metal layer 188 is disposed on the second metallization layer 186. A third metallization layer 190 is disposed on the third metal layer 188. A fourth metal layer 192 is disposed on the third metallization layer 190. The passivation layer 140 is disposed on the fourth metal layer 192. It is understood that any practical number of metallization layers, vias, and metal layers can be used to meet the needs of a particular application.

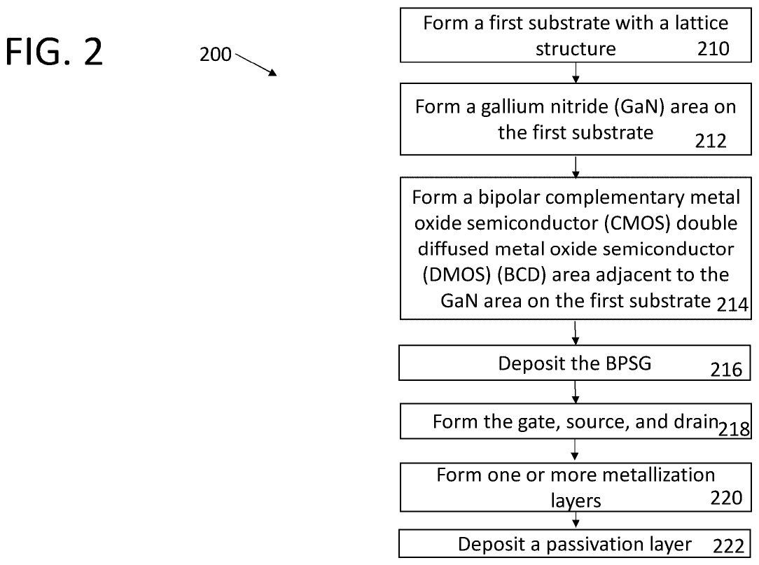

FIG. 2 shows a flowchart of an example process 200 to fabricate the semiconductor device 100 of FIG. 1. Process 200 forms a first substrate with a lattice structure in block 210. Process 200 forms a GaN area on the first substrate in block 212. Process 200 forms a bipolar junction transistor (BJT) complementary metal oxide semiconductor (CMOS) double diffused metal oxide semiconductor (DMOS) (BCD) area adjacent to the GaN area on the first substrate in block 214.

Process 200 deposits the BPSG in block 216. Process 200 forms the gate contact, source contact, and drain contact in block 218. Process 200 forms one or more metallization layers in block 220. Process 200 deposits a passivation layer in block 222.

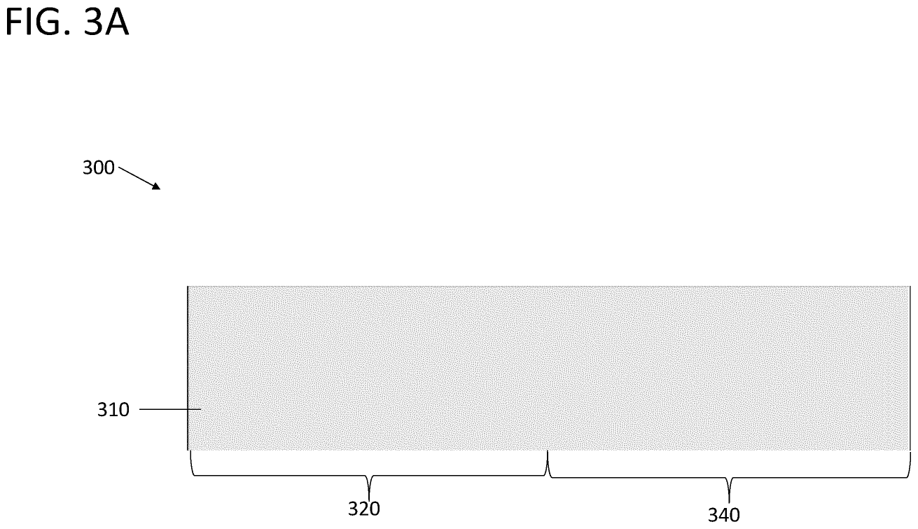

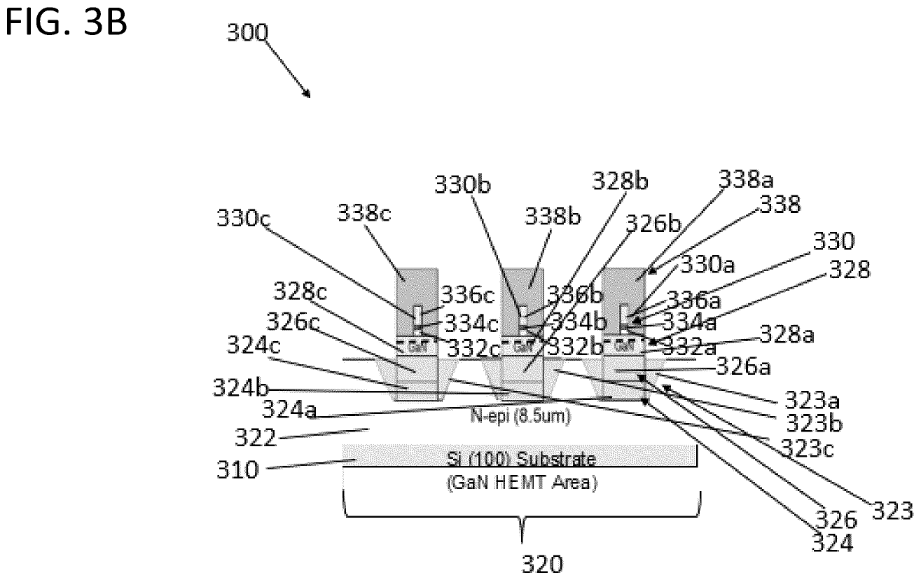

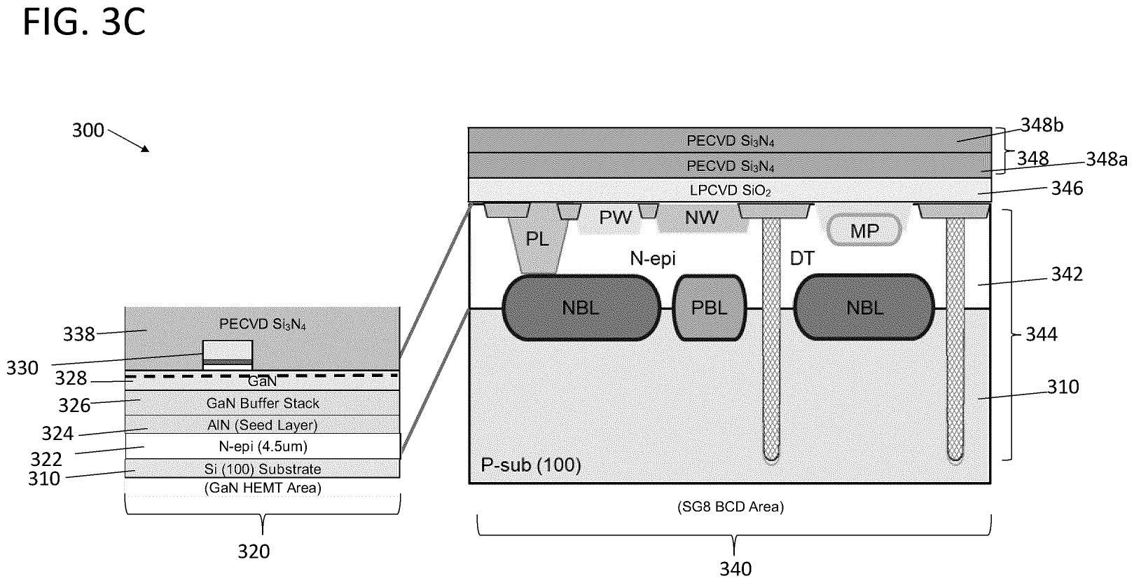

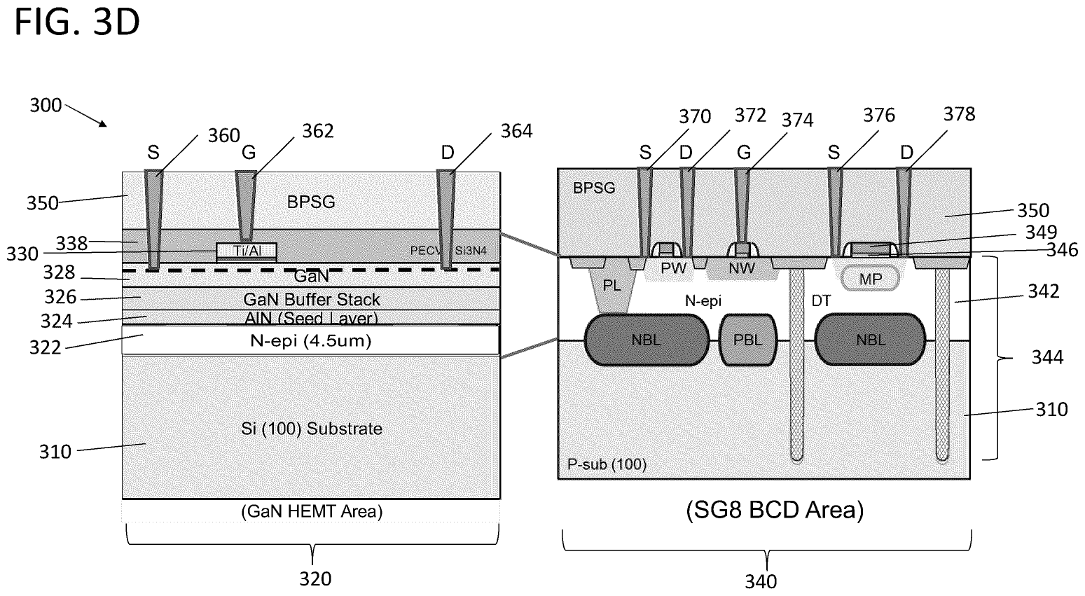

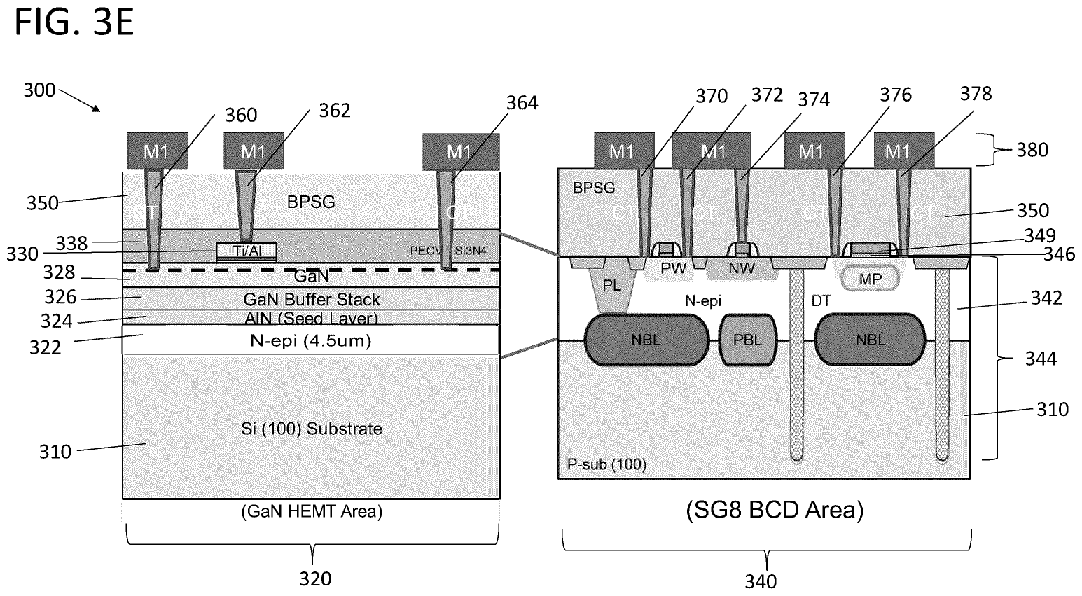

FIGS. 3A-3E describe an example of a process to fabricate the semiconductor device 100 of FIG. 1, the process is similar to or the same as process 200. FIG. 3A shows a semiconductor device 300 includes a substrate 310 having a lattice structure. The substrate 310 may be similar to or the same as substrate 102. The semiconductor device 300 shown in FIG. 3A may have been formed using the process described in block 210 in FIG. 2. Semiconductor device 300 comprises the substrate 310 having a GaN area 320 adjacent to a BCD area 340. The substrate 310 is one substrate with one lattice structure, but may be discussed herein as a GaN area substrate and a BCD area substrate to facilitate an understanding of the disclosure. The substrate 310 may be doped with a p-type dopant.

FIG. 3B shows the GaN area 320 formed on the GaN area 320 of the substrate 310. The GaN area 320 may be similar to or the same as GaN area 110. The semiconductor device 300 shown in FIG. 3B may have been formed using the process described in block 212 in FIG. 2. The GaN area 320 comprises an epitaxial layer 322 disposed on the substrate 310. The epitaxial layer 322 may be doped with an n-type dopant in order to form an n-type epitaxial layer.

One or more trenches 323 are disposed in the epitaxial layer 322. A first trench 323a is disposed adjacent to a second trench 323b, a third trench 323c is disposed adjacent to the second trench 323b. It will be appreciated by those of ordinary skill in the art, that although three trenches 323a, 323b, 323c are shown, other numbers of trenches are possible including more or fewer trenches.

One or more GaN device layers 324, 326, 328 are disposed on the epitaxial layer 322 in the trenches 323. A GaN device layer 324 comprises aluminum nitride (AlN) and is disposed on the epitaxial layer 322 in the trenches 323. A first GaN device layer 324a is disposed in the first trench 323a, a second GaN layer 324b is disposed in the second trench 323b, and a third GaN layer 324c is disposed in the third trench 323c. A GaN layer 326 is disposed on the GaN device layer 324. A first GaN layer 326a is disposed on the first GaN device layer 324a, a second GaN layer 326b is disposed on the second GaN device layer 324b, and a third GaN layer 326c is disposed on the third GaN device layer 324c. A GaN layer 328 is disposed on the GaN layer 326. GaN layer 328 may be referred to herein as a GaN epitaxial layer. A first GaN layer 328a is disposed on the first GaN layer 326a, a second GaN layer 328b is disposed on the second GaN layer 326b, a third GaN layer 328c is disposed on the third GaN layer 326c.

On the GaN layer 328 is a structure 330 formed out of a p-GaN layer, an aluminum gallium nitride (AlGaN) layer, a GaN layer, and a gate metal layer. A first structure 330a is disposed on the first GaN layer 328a, a second structure 330b is disposed on the second GaN layer 328b, and a third structure 330c is disposed on the third GaN layer 328c. The AlGaN layer is disposed on the GaN layer 328. A first AlGaN layer 332a is disposed on the first GaN layer 328a, a second AlGaN layer 332b is disposed on the second GaN layer 328b, and a third AlGaN layer 332c is disposed on the third GaN layer 328c. The p-GaN layer is disposed on the AlGaN layer. A first p-GaN layer 334a is disposed on the first AlGaN layer 332a, a second p-GaN layer 334b is disposed on the second AlGaN layer 332b, and a third p-GaN layer 334c is disposed on the third AlGaN layer 332c. The p-GaN layer may be doped with a p-type dopant to form a p-type GaN layer. The gate metal layer is disposed on the GaN layer. A first gate metal layer 336a is disposed on the first GaN layer 334a, a second gate metal layer 336b is disposed on the second GaN layer 334b, and a third gate metal layer 336c is disposed on the third GaN layer 334c. The gate metal layer 336 comprises one or more of Titanium (Ti), Titanium Nitride (TiN), Aluminum Copper (AlCu). For example, the gate metal 336 may comprise a mixture of Ti/TiN/AlCu/Ti/TiN.

A passivation layer 338 is disposed on the GaN layer 328 and the structure 330. A first passivation layer 338a is disposed on the first GaN layer 328a and the first structure 330a, a second passivation layer 338b is disposed on the second GaN layer 328b and the second structure 330b, and a third passivation layer 338c is disposed on the third GaN layer 328c and the third structure 330c. The passivation layer 338 may be formed from a silicon nitride (Si₃N₄) and disposed through a plasma-enhanced chemical vapor deposition process.

FIG. 3C shows the BCD area 340 formed adjacent to the GaN area 320 on the substrate 310. The BCD area 340 may be similar to or the same as BCD area 120. The semiconductor device 300 shown in FIG. 3C may have been formed using the process described in block 214 in FIG. 2. The BCD area 340 of the substrate 310 may be doped with a p-type dopant in order to form a p-type substrate.

An epitaxial layer 342 is disposed on the BCD area 340 of the substrate 310. The epitaxial layer 342 may be doped with an n-type dopant in order to form an n-type epitaxial layer. One or more bipolar junction transistor (BJT or bipolar), complementary metal oxide semiconductor (CMOS), and double diffused metal oxide semiconductor (DMOS) (BCD) elements 344 are disposed within the BCD area substrate 314 and the epitaxial layer 342.

A silicon dioxide (SiO₂) layer 346 is disposed on the BCD elements 344 and the epitaxial layer 342. The SiO₂ layer 346 may be disposed through a low pressure chemical vapor deposition process. One or more silicon nitride layers 348 are disposed on the SiO₂ layer 346. A first silicon nitride layer 348a is disposed on the SiO₂ layer 346. A second silicon nitride layer 348b is disposed on the first silicon nitride layer 348a. The silicon nitride layers 348 may be disposed through a plasma-enhanced chemical vapor deposition process.

FIG. 3D shows the silicon nitride layers 348 etched away, a BPSG layer 350 deposited, and gate contact, source contact, and drain contact formed. The semiconductor device 300 shown in FIG. 3D may have been formed using the process described in blocks 216, 218 in FIG. 2. In the GaN area 320, the BPSG layer 350 is disposed on the passivation layer 338. A first source contact 360, a first gate contact 362, and a first drain contact 364 are formed in the BPSG layer 350 and the passivation layer 338 in the GaN area 320. In the BCD area 340, the BPSG layer 350 is deposited on the gate polysilicon layer 349, SiO₂ layer 346, and the BCD elements 344. A second source contact 370, a second gate contact 374, a third source contact 376, a second drain contact 372, and a third drain contact 378 are formed in the BPSG layer 350 in the BCD area 340.

FIG. 3E shows metallization layers disposed on the contacts 360, 362, 364, 370, 372, 374, 376, 378 and the BPSG layer 350. The semiconductor device 300 shown in FIG. 3E may have been formed using the process described in blocks 220 in FIG. 2. The metallization layers may be similar to or the same as the metallization layers 130 in FIG. 1. The contacts 360, 362, 364, 370, 372, 374, 376, 378 provide conductive paths from the metallization layers to the device layer elements (such as the GaN device layers 324, 326, 328, and BCD elements 344). A metal layer 380 is disposed on the BPSG layer 350, the source contacts 360, 370, 376, the drain contacts 364, 378, and the gate contacts 362, 374. The metal layer 380 comprises one or more metal layers deposited on the GaN area 320 and the BCD area 340.

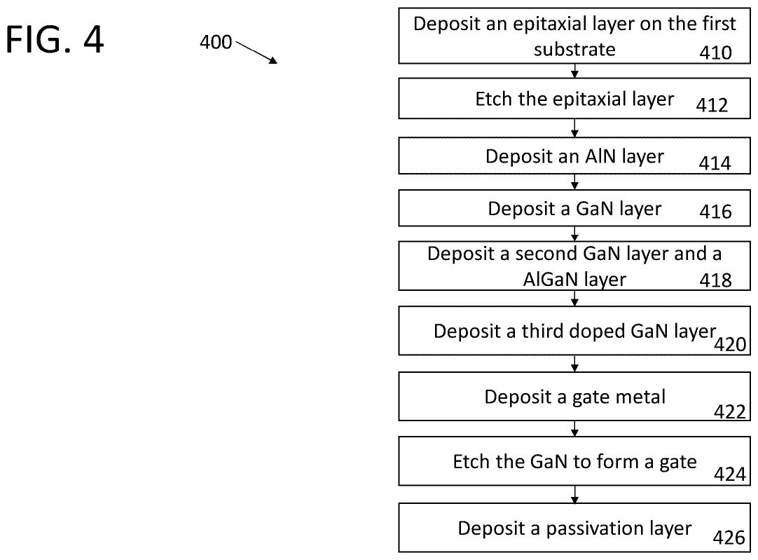

FIG. 4 is an example of a process to form a GaN area for a semiconductor device, is process 400. For example, process 400 may be used to form the GaN area 110 of semiconductor device 100. Process 400 deposits an epitaxial layer on the first substrate in block 410. The initial epitaxial layer is about 8.5 μm (+/−0.5 μm) thickness.

Process 400 etches the epitaxial layer in block 412. The initial epitaxial layer is etched to 4.5 μm (+/−0.5 μm) to form one or more GaN trenches, which levels off the GaN and BCD areas after the deposition of the GaN layers. The etch may be a plasma etch. Following, the etch forms one or more GaN trenches in the epitaxial layer and the semiconductor device is annealed. The GaN trenches are about 4 μm to 5 μm in depth (+/−0.5 μm).

Process 400 deposits an AlN layer in block 414. The deposition may include a seed layer growth nucleation of about 1 nm (+/−0.1 nm).

Process 400 deposits a first GaN layer in block 416. The GaN layer has a thickness of about 4 μm (+/−0.2 μm). The first GaN layer may be deposited through a metal-organic chemical vapor deposition (MOCVD) process with a growth temperature of about 900° C. to 1100° C. (+/−10° C.).

Process 400 deposits a second GaN layer and a AlGaN layer in block 418. The AlGaN layer may have a thickness of about 0.7 nm (+/−0.1 nm).

Process 400 deposits a third doped GaN layer in block 420. The third doped GaN may have a thickness of about 85 nm (+/−5 nm). The third doped GaN layer may be doped with a p-type dopant to form a p-type GaN layer. The p-type dopant may be magnesium (Mg) with a doping level of 6×10¹⁹ or 4×10¹⁹.

Process 400 deposits a gate metal in block 422. The gate metal may comprise a mixture of Ti/TiN/AlCu/Ti/TiN. The gate metal may form an ohmic contact. High temperature annealing may be used to activate the dopants in the third doped GaN layer.

Process 400 etches the GaN to form a gate in block 424. The process 400 etches down to gate metal and p-GaN to form a gate.

Process 400 deposits a passivation layer in block 426. The passivation layer may comprise Si₃N₄ and may be deposited through a plasma-enhanced chemical vapor deposition process.

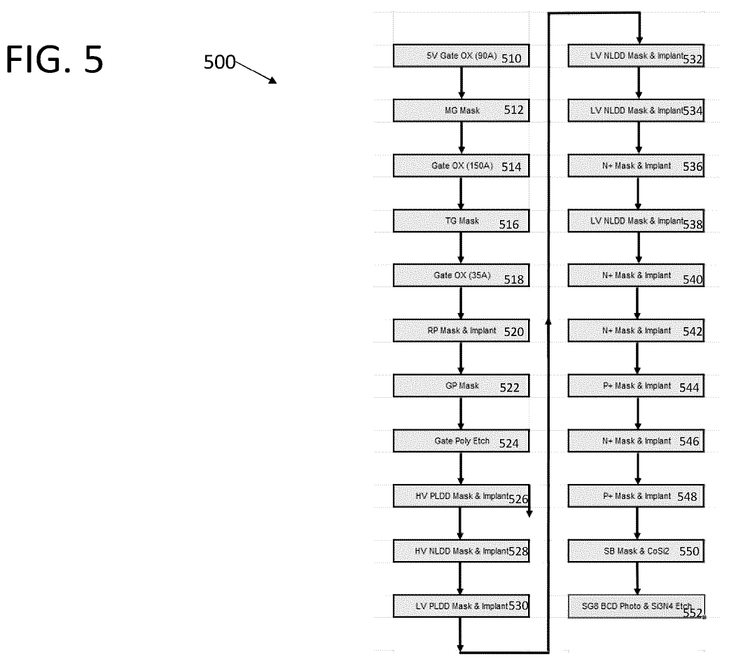

Referring now to FIG. 5, an example of a process to form a BCD area for a semiconductor device is process 500. For example, process 500 may be used to form the BCD area 120 of semiconductor device 100. Process 500 deposits a gate oxide in block 510. The gate oxide may be a 5V gate oxide (90 angstrom). Process 500 deposits a mask in block 512. The mask may be an medium gate oxide (MG) mask. Process 500 forms a gate oxide in block 514. The gate oxide may be a gate oxide (150 angstrom). Process 500 deposits a phosphorus implant (RP) mask and implant in block 520. Process 500 deposits a gate polysilicon (GP) mask in block 522.

Process 500 etches the gate polysilicon in block 524. Process 500 deposits a high voltage (HV) p-type implantation of the lightly doped diffusion (PLDD) mask and implant in block 526. Process 500 deposits a HV n-type implantation of the lightly doped diffusion (NLDD) mask and implant in block 528. Process 500 deposits a low voltage (LV) PLDD mask and implant in block 530. Process 500 deposits a LV NLDD mask and implant in block 532. Process 500 deposits a LV NLDD mask and implant in block 534. Process 500 deposits a N+ mask and implant in block 536. Process 500 deposits a LV NLDD mask and implant in block 538. Process 500 deposits a N+ mask and implant in block 540. Process 500 deposits a N+ mask and implant in block 542. Process 500 deposits a P+mask and implant in block 544. Process 500 deposits a N+ mask and implant in block 546. Process 500 deposits a P+ mask and implant in block 548. Process 500 deposits a SB mask and cobalt silicide (CoSi₂) in block 550.

Process 500 deposits a photomask and etches a passivation layer in block 552.

The BCD process delivers power integrated circuit designs with an operating voltage of up to 120V. This operating voltage enables exceptional energy efficiency and integration that combines analog circuits and digital content as well as power devices and embedded non-volatile memories (NVMs). Integration of the BCD area with the GaN area on a single substrate offers a reduction of power loss, reduction of system size, improvement of efficiency, and a reduction of cost.

Although reference is made herein to particular materials, it is appreciated that other materials having similar functional and/or structural properties may be substituted where appropriate, and that a person having ordinary skill in the art would understand how to select such materials and incorporate them into embodiments of the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” is understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

What is claimed is:

1. A semiconductor device, comprising:
a first substrate having a lattice structure, wherein the first substrate includes a gallium nitride (GaN) area adjacent to a bipolar junction transistor (BJT) complementary metal oxide semiconductor (CMOS) double diffused metal oxide semiconductor (DMOS) (BCD) area,
wherein the GaN area comprises one or more GaN device layers disposed on the first substrate and the BCD area comprises one or more BCD device layers disposed on the first substrate.

2. The semiconductor device of claim 1, wherein the first substrate comprises a silicon (100) lattice structure configuration.

3. The semiconductor device of claim 1, wherein the GaN devices layers comprise one or more GaN device layers having a cubic structure and one or more GaN device layers having a wurtzite structure.

4. The semiconductor device of claim 1, wherein the one or more GaN device layers comprise one or more GaN layers, one or more aluminum nitride (AlN) layers, one or more aluminum gallium nitride (AlGaN) layers, and one or more p-type doped p-GaN layers.

5. The semiconductor device of claim 3, further comprising an epitaxial layer between the first substrate and a first AlN layer.

6. The semiconductor device of claim 1, wherein an area of the first substrate having the BCD area further comprises an epitaxial layer with an n-type dopant and an area of the first substrate having the GaN area further comprises an epitaxial layer with an n-type dopant and a GaN epitaxial layer.

7. The semiconductor device of claim 5, wherein an epitaxial layer with an n-type dopant is disposed on the first substrate, wherein the first substrate has a p-type dopant.

8. A method, comprising:
forming a first substrate having a lattice structure;
forming a gallium nitride (GaN) area on the first substrate; and
forming a bipolar junction transistor (BJT) complementary metal oxide semiconductor (CMOS) double diffused metal oxide semiconductor (DMOS) (BCD) area adjacent to the GaN area on the first substrate,
wherein forming the GaN area comprises depositing one or more GaN device layers on the first substrate and forming the BCD area comprises depositing one or more BCD device layers on the first substrate.

9. The method of claim 8, wherein the first substrate comprises a silicon (100) lattice structure configuration.

10. The method of claim 8, wherein the GaN devices layers comprise one or more GaN device layers having a cubic structure and one or more GaN device layers having a wurtzite structure.

11. The method of claim 8, wherein forming the GaN device layers further comprises:
depositing an epitaxial layer on the first substrate;
etching the epitaxial layer on the first substrate;
depositing an AlN layer;
depositing a first GaN layer;
depositing a second GaN layer and a AlGaN layer;
depositing a third doped GaN layer;
depositing a gate metal;
etching the GaN to form a gate; and
depositing a passivation layer.

12. The method of claim 11, wherein etching the epitaxial layer on the first substrate further comprises forming one or more trenches in the epitaxial layer on the first substrate.

13. The method of claim 12, wherein the AlN layer, first GaN layer, and second GaN layer are deposited on the epitaxial layer on the first substrate in the one or more trenches.

14. The method of claim 8, wherein the first substrate having the BCD area has a p-type dopant.

15. The method of claim 14, wherein an epitaxial layer with an n-type dopant is disposed on the first substrate with a p-type dopant.

16. The method of claim 8, further comprising depositing one or more polysilicon layers on the BCD area and etching the one or more polysilicon layers.

17. The method of claim 8, further comprising depositing a borophosphosilicate glass (BPSG) layer.

18. The method of claim 17, further comprising forming one or more source contacts, one or more drain contacts, and one or more gate contacts.

19. The method of claim 8, further comprising depositing one or more metallization layers on the GaN area and the BCD area.

20. The method of claim 19, further comprising depositing a passivation layer on the one or more metallization layers.
